(19) United States
(12) Patent Application Publication
(10) Pub. No.: US 2026/0053036 A1
(43) Pub. Date: Feb. 19, 2026

(54) METHOD OF FORMING BONDING CONTACT, BONDING STRUCTURE AND SEMICONDUCTOR DEVICE

(71) Applicant: Hangzhou HFC Semiconductor Co., Hangzhou (CN)

(72) Inventors: Yuexing CHENG, Hangzhou (CN); Zhuojie WU, Hangzhou (CN); Liting HAO, Hangzhou (CN); Falong TAN, Hangzhou (CN)

(21) Appl. No.: 19/024,998

(22) Filed: Jan. 16, 2025

(30) Foreign Application Priority Data
Aug. 15, 2024 (CN) 202411119680.9

(51) Int. Cl. H01L 23/00

(52) U.S. Cl. CPC H01L 24/03; H01L 24/05; H01L 24/08; H01L 2224/03466; H01L 2224/03602; H01L 2224/05082; H01L 2224/05147; H01L 2224/05647; H01L 2224/05657; H01L 2224/05676; H01L 2224/05684; H01L 2224/08145; H01L 2924/04953

(57) ABSTRACT

A method of forming a bonding contact, a bonding structure and a semiconductor device are disclosed. The method includes forming a bonding layer. The bonding layer comprises a central region and a peripheral region. A second conductive material layer is deposited onto the surface of the bonding area, forming a capping layer. The second conductive material layer is a different conductive material from a first conductive material layer. A portion of the capping layer in the central region is removed to expose the first conductive material layer, thereby forming the bonding contact having the remaining portion of the capping layer.

### CROSS-REFERENCE TO RELATED APPLICATION

This application claims the priority of Chinese patent application number 202411119680.9, filed on Aug. 15, 2024 and entitled “METHOD OF FORMING BONDING CONTACT, BONDING STRUCTURE AND SEMICONDUCTOR DEVICE”, the entire contents of which are incorporated herein by reference.

### TECHNICAL FIELD

The present invention relates to the field of semiconductor technology, and particularly to a method of forming a bonding contact, a bonding structure and a semiconductor device.

### BACKGROUND

As the critical dimension of semiconductor devices is approaching the lower limit, planar fabrication processes and techniques are faced with more and more challenges, and becoming increasingly costly. Conventionally, semiconductor wafers or dies can be vertically stacked and connected together, for example, using through-silicon vias (TSV) or copper-to-copper (Cu—Cu) bonding, to produce 3D semiconductor devices. These 3D devices act as standalone devices and, compared with those produced using conventional planar processes, provide the advantages of reduced power consumption, a smaller footprint and higher performance. Among the various techniques for stacking semiconductor substrates, hybrid bonding is considered as one of the promising techniques, because it can be used to create high-density interconnections.

Copper-to-copper (Cu—Cu) hybrid bonding can provide high-density chip-to-chip interconnections. This technique has been widely used in cutting-edge high-performance computing (HPC), artificial intelligence (AI) and storage products. Referring to FIGS. 1 to 3, for Cu—Cu hybrid bonding, misalignment of bonding sites may lead to, among others, copper diffusion as shown by arrow a in FIG. 1, time-dependent dielectric breakdown (TDDB) as shown at b in FIG. 2, or even electromigration (EM) as shown at c in FIG. 3. All these are detrimental to reliability. In FIG. 4, 1 denotes an upper metal cap; 2, a lower metal cap; and 3, bonding sites. Conventionally, the reliability issues are counteracted by capping the bonding sites 3 with the metal caps. However, in this approach, since the metal caps and the bonding contacts are made of different conductive materials, the contact and bonding of the upper metal cap 10 and the lower metal cap 20 lead to increases in resistance and decreases in bonding strength at the bonding sites. Moreover, bonding of the metal caps may be difficult to achieve.

It should be noted that the information disclosed in this Background section is merely intended to provide a better understanding of the general context of the present invention and should not be taken as an acknowledgement or any form of admission that the information forms part of the common general knowledge of those skilled in the art.

### SUMMARY OF THE INVENTION

It is an object of the present invention to provide a method of forming a bonding contact, a bonding structure and a semiconductor device, which overcome the problems of a significant resistance and insufficient bonding strength of bonding pads associated with Cu—Cu hybrid bonding.

To this end, the present invention provides a method of forming a bonding contact, which comprises:
providing a dielectric layer and forming a trench in the dielectric layer by etching;
depositing, from the bottom upwards, a metallization layer and a first conductive material layer onto a surface of the dielectric layer that comprises the trench, thereby forming a bonding layer;
forming a bonding area on the surface of the bonding layer by polishing the bonding layer, the bonding area comprising a central region and a peripheral region;
forming a capping layer by depositing a second conductive material layer onto the surface of the bonding area, wherein the second conductive material layer is a different conductive material from the first conductive material layer;
removing a portion of the capping layer in the central region to expose the first conductive material layer, thereby forming the bonding contact with a remaining portion of the capping layer.

On the basis of the same inventive concept, the present invention also provides a bonding structure comprising:
a first bonding layer comprising a first dielectric layer, the first bonding layer comprising a first bonding contact at its surface, the first bonding contact comprising a first central region and a first peripheral region, a first conductive material layer formed in the first central region, a first capping layer formed in the first peripheral region, at least a portion of the first capping layer extending into the first central region;
a second bonding layer comprising a second dielectric layer, the second bonding layer arranged opposite to the first bonding layer, the second bonding layer comprising a second bonding contact at its surface, the second bonding contact comprising a second central region and a second peripheral region, a second conductive material layer formed in the second central region, a second capping layer formed in the second peripheral region, at least a portion of the second capping layer extending into the second central region; and
a bonding interface formed between the first and second bonding layers,
wherein at the bonding interface, the first central region is in contact with the second central region, the first dielectric layer is in contact with the second dielectric layer, and the first capping layer is at least partially in contact with the second capping layer;
the first bonding contact and the first capping layer are made of different conductive materials, and the second bonding contact and the second capping layer are of different conductive materials; and
the first and second bonding contacts are both formed according to the method as defined above.

On the basis of the same inventive concept, the present invention also provides a semiconductor device comprising:
a first semiconductor structure comprising a substrate and a first device layer formed on the substrate;
a second semiconductor structure comprising a second device layer; and
the bonding structure as defined above, which is located between and connects the first and second device layers.

Compared to the prior art, the method, bonding structure and semiconductor device of the present invention have the following advantages:

In the method, the bonding area includes the central region and the peripheral region, and a portion of the capping layer in the central region of the bonding area is removed to form the bonding contact with a remaining portion of the capping layer. The bonding contact may be bonded to another bonding contact so that the capping layers in the peripheral regions are also brought into contact with each other. The capping layers can mitigate misalignment of the two bonding contacts thus reducing copper diffusion, time-dependent dielectric breakdown (TDDB), electromigration (EM) and other reliability issues that may arise from such misalignment. Moreover, the bonding of the bonding contacts is accomplished by copper-to-copper bonding, which can prevent a resistance increase and impaired bonding strength at the bonding pads.

The bonding structure is based on the same inventive concept as, and therefore has at least all the advantages of, the method. When the bonding structure is used to establish an interconnection between chips, misalignment between bonding pads can be mitigated, preventing copper diffusion, time-dependent dielectric breakdown (TDDB), electromigration (EM) and other reliability issues. Since the first and second capping layers are provided only in the peripheral regions of the first and second bonding contacts, respectively, the first and second bonding layers can be more reliably bonded without compromising bonding strength or resistance performance.

The semiconductor device is based on the same inventive concept as, and therefore has at least all the advantages of, the bonding structure. When the bonding structure is used to establish an interconnection between chips in the semiconductor device, misalignment between bonding pads can be mitigated, preventing copper diffusion, time-dependent dielectric breakdown (TDDB), electromigration (EM) and other reliability issues. Moreover, a lower resistance and higher bonding strength can be achieved at the bonding pads, enhancing the performance of the semiconductor device.

### BRIEF DESCRIPTION OF THE DRAWINGS

FIG. 1 is a schematic diagram of a structure resulting from copper diffusion occurring during the formation of chip-to-chip interconnections according to an embodiment.

FIG. 2 is a schematic diagram of a structure resulting from time-dependent dielectric breakdown (TDDB) occurring during the formation of chip-to-chip interconnections according to an embodiment.

FIG. 3 is a schematic diagram of a structure resulting from electromigration (EM) occurring during the formation of chip-to-chip interconnections according to an embodiment.

FIG. 4 is a schematic diagram of a structure resulting from bonding pads covered by metal caps according to an embodiment.

FIG. 5 is a flowchart of a method of forming a bonding contact according to an embodiment of the present invention.

FIG. 6 is a schematic diagram of a structure resulting from the formation of a trench in a dielectric layer according to an embodiment of the present invention.

FIG. 7 is a schematic diagram of a structure resulting from the deposition of a barrier layer according to an embodiment of the present invention.

FIG. 8 is a schematic diagram of a structure resulting from the deposition of a seed layer according to an embodiment of the present invention.

FIG. 9 is a schematic diagram of a structure resulting from the formation of the bonding contact as a result of depositing a copper conductive material according to an embodiment of the present invention.

FIG. 10 is a schematic diagram of a structure resulting from mechanical polishing of the bonding contact of FIG. 9 according to an embodiment of the present invention.

FIG. 11 is a schematic diagram of a structure resulting from the deposition of a capping layer onto the bonding contact that has undergone the mechanical polishing according to an embodiment of the present invention.

FIG. 12 is a schematic diagram of a structure resulting from removal of the capping layer in a central region of the bonding contact according to an embodiment of the present invention.

FIG. 13 is a schematic top view of the structure of FIG. 12.

FIG. 14 is a schematic diagram of a structure resulting from bonding of a first bonding layer to a second bonding layer according to an embodiment of the present invention.

FIG. 15 is a schematic diagram of a structure resulting from bonding of a first bonding layer to a second bonding layer according to another embodiment of the present invention.

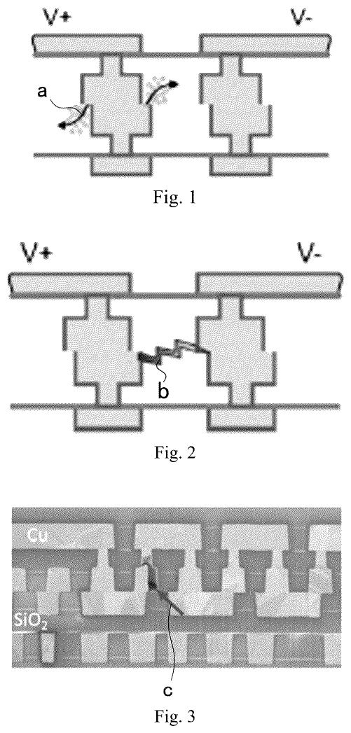

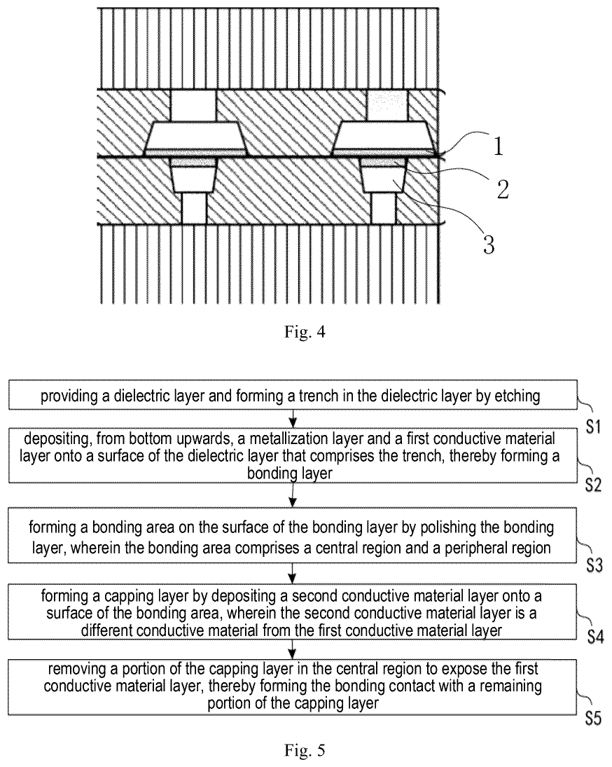

### LIST OF REFERENCE NUMERALS

1, upper metal cap; 2, lower metal cap; 3, bonding pad; 10, first bonding layer; 20, second bonding layer; 100, dielectric layer; 110, first dielectric layer; 120, second dielectric layer; 200, trench; 300, barrier layer; 400, seed layer; 500, first conductive material layer; 600, capping layer; 610, first capping layer; 620, second capping layer; 700, bonding contact; 710, first bonding contact; 720, second bonding contact; 1000, bonding structure.

### DETAILED DESCRIPTION

Objects, features and advantages of the present invention will become more apparent upon reading, in conjunction with the accompanying drawings, the following more detailed description of methods of forming a bonding contact, bonding structures and semiconductor devices according to specific embodiments of the invention. Note that the figures are provided in a very simplified form not necessarily drawn to exact scale for the only purpose of helping explain the disclosed embodiments in a more convenient and clearer way. It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment. Moreover, in the embodiments described below, identical or functionally identical parts are sometimes designated with the same reference numerals among different figures, and repeated description thereof will be omitted. As used herein, same reference numerals and letters refer to same items in the annexed figures, and thus once an item is defined in one figure, it may not be discussed or further defined in the following figures.

In addition, use of the terms “first” and “second” herein is intended for illustration only and is not to be construed as denoting or implying relative importance or as implicitly indicating the number of the referenced features. Therefore, describing a feature with the term “first” or “second” can explicitly or implicitly indicate the presence of at least one of the referenced feature. As used herein, the term “plurality” means at least two, for example, two, three or the like, unless otherwise clearly specified.

Reference throughout this specification to “one embodiment”, “some embodiments”, “an example”, “a specific example”, “some examples” or the like means that a particular feature, structure, material, or characteristic described in connection with the embodiments or examples is included in at least one embodiment of the invention or example thereof. Thus, the appearances of those phrases in various places throughout this specification are not necessarily referring to the same embodiment of the invention or example thereof. Furthermore, the particular features, structures, materials, or characteristics may be combined in any suitable manner in any one or more embodiments. Further, should there be no contradiction, one of ordinary skill in the art can combine the various embodiments, examples and features thereof described herein in any combination.

As used hereinafter, the term “layer” refers to a material including a portion having a thickness. A layer may extend over the entirety of an underlying or overlying structure, or may have an extent smaller than an extent of the underlying or overlying structure. In addition, a layer may be a homogeneous or inhomogeneous region, which has a smaller thickness than the continuous structure. For example, a layer may be located between top and bottom surfaces of a continuous structure, or between any pair of horizontal planes at the top and bottom surfaces. A layer may extend horizontally, vertically and/or along an inclined surface. A substrate may consist of a layer, which includes one or more layers therein, and/or be covered by, underlie and/or overlie one or more layers. A layer may include multiple layers. For example, a dielectric layer 100 may include one or more insulating layers.

As used hereinafter, the phase “from the bottom upwards” may be used to describe a bonding layer with a side formed with a bonding contact being defined as an upper side and the opposite side as a bottom side.

Essentially, the present invention seeks to provide a method of forming a bonding contact, a bonding structure and a semiconductor device, which can overcome not only copper diffusion, time-dependent dielectric breakdown (TDDB), electromigration (EM) and other reliability issues but also the problems of an increased resistance and impaired bonding strength of bonding pads.

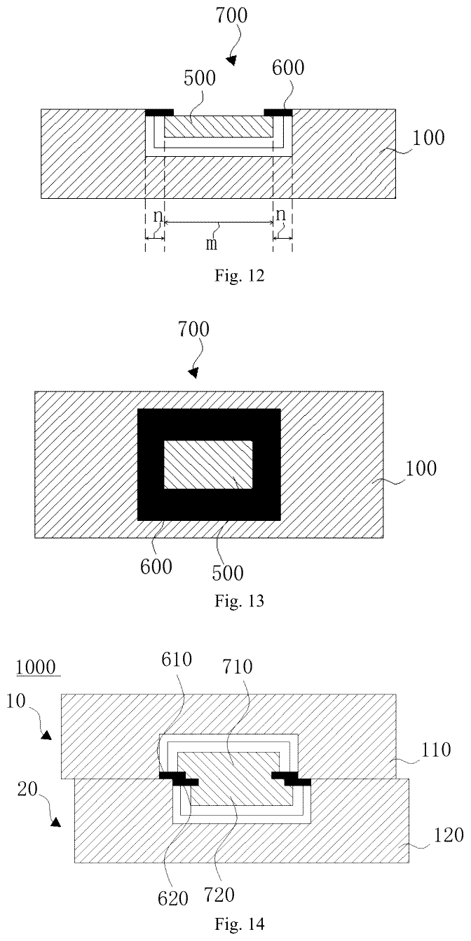

To this end, the present invention provides a method of forming a bonding contact. Reference is now made to FIGS. 5 to 15, which illustrate a specific embodiment of the method. As shown, the method includes steps S1 to S5 as described below.

Step S1: Provide a dielectric layer and form a trench 200 therein by etching.

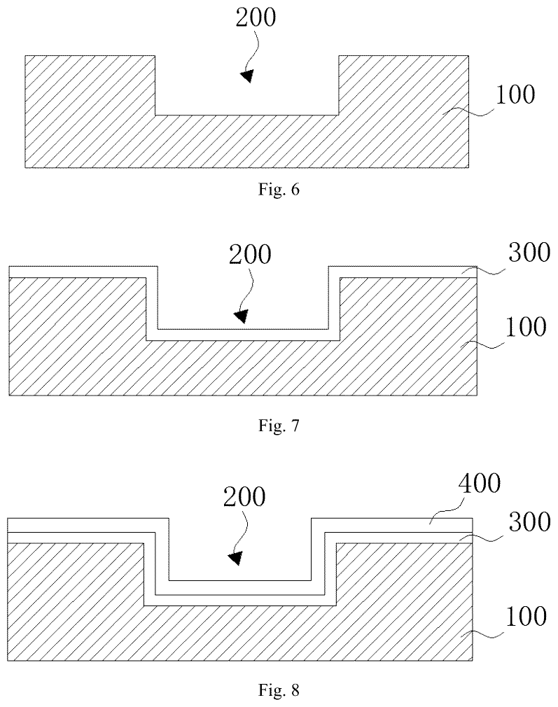

Specifically, referring to FIGS. 5 and 6, in particular, the formation of the trench 200 may involve first coating photoresist on the surface of the dielectric layer 100. A pattern may be then transferred from a photomask to the photoresist by exposure and development. Finally, the trench 200 may be formed by etching the dielectric layer 100, as shown in FIG. 6, followed by removal of the photoresist. In this way, the structure shown in FIG. 6 can be obtained. It is noted that the formation of the trench 200 in the dielectric layer 100 by etching may be accomplished using a conventional process well known to those skilled in the art and, therefore, needs not be described in further detail herein.

The dielectric layer 100 is an insulating material and is formed between different device layers to provide insulation and isolation. The material of the dielectric layer 100 may be silicon nitride, silicon oxynitride, silicon oxide or a combination thereof. Alternatively, it may also be another common insulating material, without departing from the scope of the invention.

Step S2: Successively deposit, from the bottom upwards, a metallization layer and a first conductive material layer 500 onto the surface of the dielectric layer, thereby forming a bonding layer.

Specifically, referring to FIGS. 5 to 9, the successive deposition of the metallization layer and the first conductive material layer 500 from the bottom upwards onto the surface of the dielectric layer may include the steps detail below.

First of all, a barrier layer 300 is deposited onto the surface of the dielectric layer which comprises the trench 200, forming the structure of FIG. 7. The barrier layer 300 may be tantalum nitride or another material and can effectively prevent the first conductive material from diffusing into the dielectric layer 100.

Next, a seed layer 400 is deposited onto the surface of the barrier layer 300, forming the structure of FIG. 8. The seed layer 400 is a copper-based seed layer optionally made of copper or a copper alloy, which allows a copper plating process to be carried out subsequently.

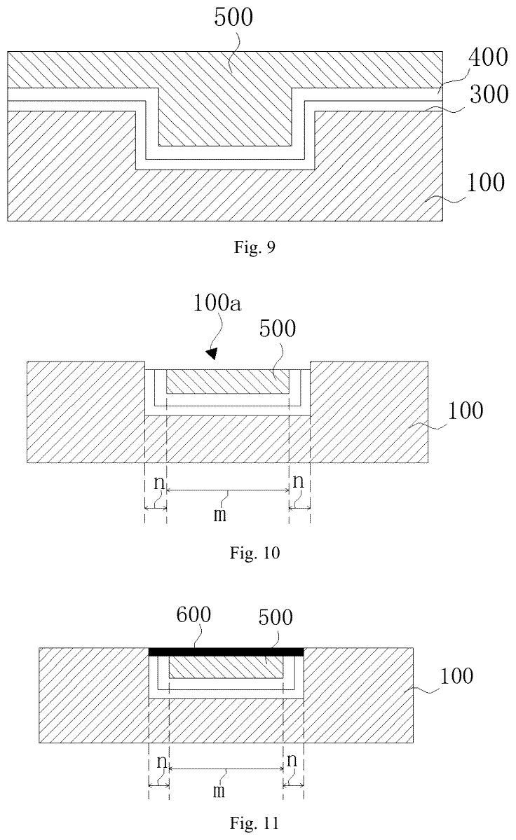

Finally, the first conductive material layer 500 is deposited onto the surface of the copper seed layer, forming the structure of FIG. 9. The first conductive material layer 500 may be copper, aluminum, an aluminum-copper or other copper alloy, or other conventional conductive material. In this embodiment, the first conductive material is preferred to be copper. It can connect integrated circuits in various chips to external structures. That is, a copper metal layer is preferably formed on the surface of the copper seed layer.

Step S3: Polish the bonding layer to form a bonding area 100a on the surface of the bonding layer. The bonding area 100a includes a central region m and a peripheral region n.

Specifically, referring to FIGS. 5 and 10, polishing the bonding layer may include: removing a portion of the first conductive material layer 500, a portion of the barrier layer 300 and a portion of the seed layer 400 by chemical mechanical polishing, with only remaining portions of the barrier layer 300, the seed layer 400 and the first conductive material layer 500 within the trench 200 being retained. As a result, the bonding area 100a is formed on the surface of the bonding layer. One or more chemical mechanical polishing processes may be carried out on the surface of the bonding layer, without departing from the scope of the invention.

The bonding area 100a includes a central region m and a peripheral region n.

Step S4: Deposit a second conductive material layer onto the surface of the bonding area 100a, forming a capping layer 600. The second conductive material layer is a different conductive material from the first conductive material layer 500.

Particular reference is now made to FIGS. 5 and 11. The capping layer 600 may be formed by depositing the second conductive material layer onto the surface of the bonding area 100a by chemical vapor deposition, forming the structure of FIG. 11. Differing from the first conductive material layer 500 which is copper, the second conductive material layer may be any of cobalt, cobalt-tungsten-phosphorus alloy and ruthenium, or any combination thereof. That is, the second conductive material layer may be cobalt metal, a cobalt-tungsten-phosphorus alloy, or ruthenium metal. Alternatively, it may be any combination of the three metal materials. Since the second conductive material layer possesses good anti-diffusion and anti-oxidation properties, the capping layer 600 also has good anti-diffusion and anti-oxidation properties. The following description is made in the context of the second conductive material layer being implemented as cobalt, as an example. As the materials are polished at different rates, a recess may appear in copper metal in the trench 200. Cobalt metal may be then deposited into the recess, forming the capping layer 600. This can ensure a flat surface of the bonding layer. It is noted that, even when no recess forms in the copper metal layer as a result of the chemical mechanical polishing process carried out on the bonding layer, it is within the contemplation of the present invention to form a bump on the bonding layer as a result of the deposition of cobalt metal for forming the capping layer 600. It is also noted that the present invention is not limited to any particular thickness of the resulting capping layer 600 and the thickness may be determined as required in practical wafer fabrication applications. Further, the capping layer 600 may have any suitable width and length, as long as they allow the bonding area 100a to be completely capped and protected against copper diffusion, time-dependent dielectric breakdown (TDDB), electromigration (EM) and other reliability issues.

Step S5: Remove portion of the capping layer 600 in the central region m to expose the first conductive material layer 500, thereby forming the bonding contact 700 having the remaining portion of the capping layer 600.

Specifically, referring to FIGS. 5, 12 and 13, a portion of the capping layer 600 in the central region m is removed to expose the first conductive material layer 500, thereby forming the bonding contact 700 with the remaining portion of the capping layer 600. The bonding contact 700 forms the bonding sites mentioned in the Background section, and is also known as a bonding pad, to achieve a metal interconnect between different chips. Referring to FIG. 13, the capping layer 600 of the bonding contact 700 is a closed quadrilateral structure and may be also referred to as a metal cap. It covers the periphery of the copper metal layer to prevent copper diffusion. It is noted that the present invention is not limited to any particular shape of the capping layer 600, and it may have a circular, elliptical or quadrilateral shape, or any combination of these shapes. In order to allow the bonding contact 700 to have a larger contact area, the removed portion of the capping layer 600 may have a larger area than the remaining portion of the capping layer in the central region m.

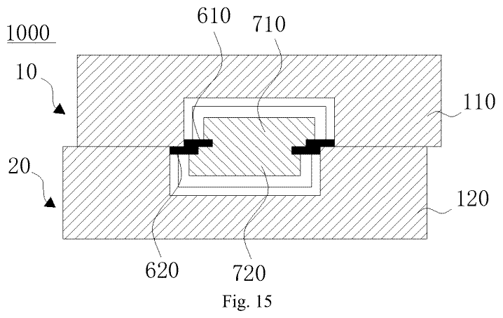

Referring to FIGS. 14 and 15, in order to bond the bonding contacts 700 (e.g. bonding the first bonding contacts 710 to the second bonding contacts 720), it may be moved in the X direction so that the first capping layer 610 is located at either a −X location, as shown in FIG. 14, or to a +X location, as shown in FIG. 15, with respect to the second capping layer 620. The bonding can be accomplished as long as the first capping layer 610 at least partially contacts the second capping layer 620, the first bonding contact 710 contacts the second bonding contact 720 and the first dielectric layer 110 contacts the second dielectric layer 120. Of course, the first capping layer 610 and the second capping layer 620 may also be in complete coincidence and contact with each other.

In this method, the bonding area 100a includes the central region m and the peripheral region n, and the portion of the capping layer 600 in the central region m of the bonding area 100a is removed to form the bonding contact 700 having the remaining portion of the capping layer 600. The bonding contact 700 may be bonded to another bonding contact 700 so that the capping layers 600 in the peripheral regions n are also brought into contact with each other. The capping layers 600 can mitigate misalignment of the two bonding contacts 700, thus reducing copper diffusion, time-dependent dielectric breakdown (TDDB), electromigration (EM) and other reliability issues that may arise from such misalignment. Moreover, the bonding of the bonding contacts 700 is accomplished by copper-to-copper bonding, which can prevent a resistance increase and impaired bonding strength at the bonding pads.

The above object is also attained by a bonding structure 1000 according to an embodiment of the present invention. As shown, the bonding structure 1000 includes a first bonding layer 10 comprising a first dielectric layer 110. The first bonding layer 10 comprises a first bonding contact 710 at its surface. The first bonding contact 710 comprises a first central region and a first peripheral region and a first conductive material layer 500 is formed in the first central region and a first capping layer 610 is formed in the first peripheral region. The first capping layer 610 extends at least partially into the first central region. The bonding structure 1000 further includes a second bonding layer 20 comprising a second dielectric layer 120, the second bonding layer 20 is arranged opposite to the first bonding layer 10. The second bonding layer 20 has a second bonding contact 720 at its surface. The second bonding contact 720 comprises a second central region and a second peripheral region and a first conductive material layer 500 is formed in the second central region and a second capping layer 620 is formed in the second peripheral region. The second capping layer 620 extends at least partially into the second central region. The bonding structure 1000 further includes a bonding interface formed between the first bonding layer 10 and the second bonding layer 20. At the bonding interface, the first central region is in contact with the second central region, the first dielectric layer 110 is in contact with the second dielectric layer 120, and the first capping layer 610 is at least partially in contact with the second capping layer 620. The first bonding contact 710 and the first capping layer 610 are formed of different conductive materials, and the second bonding contact 720 and the second capping layer 620 are formed of different conductive materials. The conductive material of each of the first bonding contact 710 and the second bonding contact 720 is copper, and the conductive material of each of the first capping layer 610 and the second capping layer 620 is any of cobalt, a cobalt-tungsten-phosphorus alloy and ruthenium or any combination thereof. Each of the first bonding contact 710 and the second bonding contact 720 may be formed according to the method as defined above.

It is noted that each of the first and second central regions corresponds to the central region m of the bonding area 100a, as discussed above. Moreover, each of the first and second peripheral regions corresponds to the peripheral region n of the bonding area 100a, as discussed above.

The bonding structure 1000 is based on the same inventive concept as the above-discussed method. Therefore, it has at least all the advantages of the method. When the bonding structure 1000 is used to establish an interconnection between chips, misalignment between bonding pads can be mitigated, preventing copper diffusion, time-dependent dielectric breakdown (TDDB), electromigration (EM) and other reliability issues. Since the first capping layer 610 and the second capping layer 620 are provided only in the peripheral regions of the first bonding contact 710 and the second bonding contact 720, respectively, the first bonding layer 10 and the second bonding layer 20 can be more reliably bonded without compromising bonding strength or resistance performance.

The above object is also attained by a semiconductor device including: a first semiconductor structure including a substrate and a first device layer formed on the substrate; a second semiconductor structure including a second device layer; and the bonding structure 1000 as defined above. The bonding structure 1000 is located between the first and second device layers and connects the first and second device layers.

The first and second semiconductor device layers are isolated from each other by a dielectric layer 100 deposited therebetween and interconnected to each other by the bonding structure 1000.

It is noted that, as used hereinabove, the term “substrate” refers to a material, on top of which one or more other materials can be deposited subsequently. A substrate can itself be patterned, and in this case, one or more materials deposited on top of the substrate may be also patterned or not. A substrate may be made of any of a wide range of semiconductor materials, such as silicon, germanium, gallium arsenide, indium phosphide, etc. A substrate may also be made of a non-conductive material such as a glass, plastic or sapphire wafer.

The first and second semiconductor structures may include a peripheral device layer formed on the substrate. The peripheral device layer may include multiple transistors formed on the substrate. A transistor may be formed on a substrate and may be entirely or partly embedded in the substrate and/or directly formed on the substrate. In some embodiments, the peripheral device layer may include any appropriate peripheral circuits for transmitting digital, analog, and/or mixed signals, which can facilitate operation of the semiconductor device. For example, the peripheral device layer may include one or more of page buffers, decoders (e.g., row decoders and column decoders), sense amplifiers, drivers, charge pumps, current or voltage references and any active or passive circuit components (e.g., transistors, diodes, resistors and capacitors). In some embodiments, the peripheral device layer is formed on the substrate using a complementary metal-oxide-semiconductor (CMOS) process.

The semiconductor device is not limited to being implemented as a memory device, and may be alternatively implemented as any suitable semiconductor device, for which the performance of a bonding interface can be enhanced by capping layers 600. In some embodiments, the semiconductor device is a NAND flash memory device including memory cells provided by an array of NAND memory strings each extending vertically above the peripheral device layer.

The semiconductor device is based on the same inventive concept as the above bonding structure 1000. Therefore, it has at least all the advantages of the bonding structure 1000. When the bonding structure 1000 is used to establish an interconnection between chips in the semiconductor device, misalignment between bonding sites therein can be mitigated, preventing copper diffusion, time-dependent dielectric breakdown (TDDB), electromigration (EM) and other reliability issues. Moreover, a lower resistance and higher bonding strength can be achieved at the bonding sites, enhancing the performance of the semiconductor device.

In summary, methods of forming a bonding contact, bonding structures and semiconductor devices of various configurations constructed in accordance with the present invention have been described in detail above with reference to the foregoing embodiments. Of course, the above description is merely that of some preferred modes of carrying out the invention and is in no way intended to limit the scope thereof. Possible configurations of the present invention include, but are not limited to, those described in the foregoing embodiments, and those skilled in the art can obtain more configurations in light of the above teachings. Accordingly, any and all variations and modification made by those of ordinary skill in the art to which the present invention pertains in light of the above teachings are intended to fall within the scope thereof as defined by the appended claims.

What is claimed is:

1. A method of forming a bonding contact, comprising:
providing a dielectric layer and forming a trench in the dielectric layer by etching;
depositing a barrier layer onto a surface of the dielectric layer that comprises the trench, depositing a seed layer onto a surface of the barrier layer and depositing a first conductive material layer onto a surface of the copper seed layer, thereby forming a bonding layer over the dielectric layer;
polishing the bonding layer to form a bonding area on a surface of the bonding layer, wherein the bonding area comprises a central region and a peripheral region;
forming a capping layer by depositing a second conductive material layer onto the bonding area, wherein the second conductive material layer is a different conductive material from the first conductive material layer;
removing a portion of the capping layer in the central region to expose the first conductive material layer, thereby forming a bonding contact with a remaining portion of the capping layer.

2. The method according to claim 1, wherein the seed layer is a copper seed layer.

3. The method according to claim 2, wherein the barrier layer is a tantalum nitride layer.

4. The method according to claim 1, wherein the first conductive material layer is copper, and the second conductive material layer is one of cobalt, a cobalt-tungsten-phosphorus alloy and ruthenium, or any combination thereof.

5. The method according to claim 1, wherein polishing the bonding layer to form the bonding area on the surface of the bonding layer comprises:
removing a portion of the barrier layer, a portion of the copper seed layer and a portion of the first conductive material layer of the bonding layer through chemical mechanical polishing, thereby forming the bonding area at the trench.

6. A bonding structure, comprising:
a first bonding layer comprising a first dielectric layer, wherein: the first bonding layer comprises a first bonding contact at a surface thereof; the first bonding contact comprises a first central region and a first peripheral region; a first conductive material layer is formed in the first central region; a first capping layer is formed in the first peripheral region; and at least a portion of the first capping layer extends into the first central region;
a second bonding layer comprising a second dielectric layer, wherein the second bonding layer is arranged opposite to the first bonding layer; the second bonding layer comprises a second bonding contact at a surface thereof; the second bonding contact comprises a second central region and a second peripheral region; a second conductive material layer is formed in the second central region; a second capping layer is formed in the second peripheral region; and at least a portion of the second capping layer extends into the second central region; and
a bonding interface formed between the first and second bonding layers,
wherein at the bonding interface, the first central region is in contact with the second central region, the first dielectric layer is in contact with the second dielectric layer, and the first capping layer is at least partially in contact with the second capping layer;
wherein the first bonding contact and the first capping layer are made of different conductive materials, and the second bonding contact and the second capping layer are of different conductive materials; and
wherein formation of each of the first and second bonding contacts comprises:
providing a dielectric layer and forming a trench in the dielectric layer by etching;
depositing a barrier layer onto a surface of the dielectric layer that comprises the trench, depositing a seed layer onto a surface of the barrier layer and depositing a first conductive material layer onto a surface of the copper seed layer, thereby forming a bonding layer over the dielectric layer;
polishing the bonding layer to form a bonding area on a surface of the bonding layer, wherein the bonding area comprises a central region and a peripheral region;
forming a capping layer by depositing a second conductive material layer onto the bonding area, wherein the second conductive material layer is a different conductive material from the first conductive material layer;
removing a portion of the capping layer in the central region to expose the first conductive material layer, thereby forming the bonding contact with a remaining portion of the capping layer.

7. The bonding structure according to claim 6, wherein the seed layer is a copper seed layer.

8. The bonding structure according to claim 7, wherein the barrier layer is a tantalum nitride layer.

9. The bonding structure according to claim 6, wherein polishing the bonding layer to form the bonding area on the surface of the bonding layer comprises:
removing a portion of the barrier layer, a portion of the copper seed layer and a portion of the first conductive material layer of the bonding layer through chemical mechanical polishing, thereby forming the bonding area at the trench.

10. The bonding structure according to claim 6, wherein the conductive material of each of the first and second bonding contacts is copper, and the conductive material of each of the first and second capping layers is one of cobalt, a cobalt-tungsten-phosphorus alloy and ruthenium, or any combination thereof.

11. A semiconductor device, comprising:
a first semiconductor structure comprising a substrate and a first device layer formed on the substrate;
a second semiconductor structure comprising a second device layer; and
the bonding structure of claim 6, wherein the bonding structure is located between and connects the first and second device layers.
